(19) United States
(12) Patent Application Publication
(10) Pub. No.: US 2022/0115407 A1
(43) Pub. Date: Apr. 14, 2022

(54) ARRAY SUBSTRATE AND DISPLAY PANEL

(71) Applicant: Shenzhen China Star Optoelectronics Semiconductor Display Technology Co., Ltd., Shenzhen, Guangdong (CN)

(72) Inventors: Munan Lin, Shenzhen, Guangdong (CN); Bangyin Peng, Shenzhen, Guangdong (CN); Ilgon Kim, Shenzhen, Guangdong (CN)

(73) Assignee: Shenzhen China Star Optoelectronics Semiconductor Display Technology Co., Ltd., Shenzhen, Guangdong (CN)

(21) Appl. No.: 16/770,303

(22) PCT Filed: May 21, 2020
(86) PCT No.: PCT/CN2020/091615

§ 371 Date: Jun. 5, 2020

(30) Foreign Application Priority Data
May 14, 2020 (CN) 2020 10406828.2

(51) Int. Cl. H01L 27/12; G02F 1/1362

(52) U.S. Cl. CPC H01L 27/124; H01L 27/1255; G02F 1/136286

(57) ABSTRACT

An array substrate and a display panel are provided. The array substrate includes one or more sub-pixels, and one or more connecting members corresponding to the first sub-pixels. A layer where the connecting members are located is insulated from the source/drain layer. Data lines connected to the first sub-pixels include first sub-data lines adjacent to the first sub-pixels. Both ends of each of the connecting members are connected to a corresponding first sub-data line through via holes. This improves a charging rate of sub-pixels.

### FIELD OF INVENTION

The present disclosure relates to the technical field of display, and particularly to an array substrate and a display panel.

### BACKGROUND

With the development of flat panel display technology, 8K resolution has become a development trend of panels. Current 8K array substrates have larger sizes and higher refresh rates, so when scanning lines turn on pixels line by line, each of the scanning lines has a shorter scanning time. This shortens writing time of data signals, resulting in insufficient charging rates, which affects display effects of display panels.

Therefore, there is a need to improve the technical problem of insufficient charging rates of pixels of current display panels.

### SUMMARY OF DISCLOSURE

The present disclosure provides an array substrate and a display panel to solve the technical problem of insufficient charging rates of pixels of current display panels.

In order to solve the above problem, the present disclosure provides the following technical solutions.

The present disclosure provides an array substrate comprising a plurality of sub-pixels disposed in an array and further comprising:

a substrate;

a first metal layer disposed on a side of the substrate and patterned to form a plurality of scan lines, wherein the scan lines extend in a horizontal direction and are disposed at intervals in a vertical direction, and each of the scan lines connects to a row of the sub-pixels;

an insulating layer disposed on a side of the first metal layer away from the substrate; and

a source/drain layer disposed on a side of the insulating layer away from the first metal layer and patterned to form a plurality of data lines, wherein the data lines extend in the vertical direction and are disposed at intervals in the horizontal direction, and each of the data lines connects to a column of the sub-pixels;

wherein, the sub-pixels comprise one or more first sub-pixels, the array substrate is provided with one or more connecting members corresponding to the first sub-pixels, a layer where the connecting members are located is insulated from the source/drain layer, the connecting members are not connected with other structures formed of the layer where the connecting members are located, the data lines connected to the first sub-pixels comprise first sub-data lines adjacent to the first sub-pixels, and both ends of each of the connecting members are connected to a corresponding first sub-data line through via holes.

In the array substrate, the connecting members are formed of the first metal layer.

In an embodiment, the array substrate further comprises a second metal layer disposed between and insulated from the first metal layer and the source/drain layer. The first metal layer further forms a first plate of a storage capacitor. The second metal layer further forms a second plate of the storage capacitor. The connecting members are formed of at least one of the first metal layer and the second metal layer.

In the array substrate, the connecting members are parallel to the first sub-data lines.

In an embodiment, the array substrate is provided with two or more of the connecting members corresponding to the first sub-pixels and spaced apart from each other.

In an embodiment, the array substrate further comprises a first area. The first area comprises one or more columns of the first sub-pixels. Each of the scan lines is connected to a scan signal input terminal. A distance between the first area and each of the scan signal input terminals is greater than a threshold.

In the array substrate, the scan signal input terminals are disposed on a left or right side of the array substrate, and the first area is located on a side of a pixel area of the array substrate away from the scan signal input terminals.

In the array substrate, the scan signal input terminals are disposed on left and right sides of the array substrate, and the first area is located in a middle of a pixel area of the array substrate.

In the array substrate, the first area has a same size as a pixel area of the array substrate.

In the first area of the array substrate, the connecting members corresponding to the first sub-pixels are disposed in a same manner.

The present disclosure further provides a liquid crystal display panel comprising an array substrate and a color film substrate disposed oppositely. The array substrate comprises a plurality of sub-pixels disposed in an array and further comprises:

a substrate;

a first metal layer disposed on a side of the substrate and patterned to form a plurality of scan lines, wherein the scan lines extend in a horizontal direction and are disposed at intervals in a vertical direction, and each of the scan lines connects to a row of the sub-pixels;

an insulating layer disposed on a side of the first metal layer away from the substrate; and

a source/drain layer disposed on a side of the insulating layer away from the first metal layer and patterned to form a plurality of data lines, wherein the data lines extend in the vertical direction and are disposed at intervals in the horizontal direction, and each of the data lines connects to a column of the sub-pixels;

wherein, the sub-pixels comprise one or more first sub-pixels, the array substrate is provided with one or more connecting members corresponding to the first sub-pixels, a layer where the connecting members are located is insulated from the source/drain layer, the connecting members are not connected with other structures formed of the layer where the connecting members are located, the data lines connected to the first sub-pixels comprise first sub-data lines adjacent to the first sub-pixels, and both ends of each of the connecting members are connected to a corresponding first sub-data line through via holes.

In the liquid crystal display panel, the connecting members are formed of the first metal layer.

In the liquid crystal display panel, the array substrate further comprises a second metal layer disposed between and insulated from the first metal layer and the source/drain layer. The first metal layer further forms a first plate of a storage capacitor. The second metal layer further forms a second plate of the storage capacitor. The connecting members are formed of at least one of the first metal layer and the second metal layer.

In the liquid crystal display panel, the connecting members are parallel to the first sub-data lines.

In the liquid crystal display panel, the array substrate is provided with two or more of the connecting members corresponding to the first sub-pixels and spaced apart from each other.

In the liquid crystal display panel, the array substrate further comprises a first area. The first area comprises one or more columns of the first sub-pixels. Each of the scan lines is connected to a scan signal input terminal. A distance between the first area and each of the scan signal input terminals is greater than a threshold.

In the liquid crystal display panel, the scan signal input terminals are disposed on a left or right side of the array substrate, and the first area is located on a side of a pixel area of the array substrate away from the scan signal input terminals.

In the liquid crystal display panel, the scan signal input terminals are disposed on left and right sides of the array substrate, and the first area is located in a middle of a pixel area of the array substrate.

In the liquid crystal display panel, the first area has a same size as a pixel area of the array substrate.

In the first area of the liquid crystal display panel, the connecting members corresponding to the first sub-pixels are disposed in a same manner.

The present disclosure provides an array substrate and a display panel. The array substrate comprises a plurality of sub-pixels disposed in an array. The array substrate further comprises a substrate, a first metal layer, an insulating layer, and a source/drain layer. The first metal layer is disposed on a side of the substrate and is patterned to form a plurality of scan lines. The scan lines extend in a horizontal direction and are disposed at intervals in a vertical direction. Each of the scan lines connects to a row of the sub-pixels. The insulating layer is disposed on a side of the first metal layer away from the substrate. The source/drain layer is disposed on a side of the insulating layer away from the first metal layer and is patterned to form a plurality of data lines. The data lines extend in the vertical direction and are disposed at intervals in the horizontal direction. Each of the data lines connects to a column of the sub-pixels. The sub-pixels comprise one or more first sub-pixels. The array substrate is provided with one or more connecting members corresponding to the first sub-pixels. A layer where the connecting members are located is insulated from the source/drain layer. The connecting members are not connected with other structures formed of the layer where the connecting members are located. The data lines connected to the first sub-pixels comprise first sub-data lines adjacent to the first sub-pixels. Both ends of each of the connecting members are connected to a corresponding first sub-data line through via holes. In the present invention, a data line corresponding to at least one sub-pixel in an array substrate is connected to both ends of a connecting member, so that the data line is connected in parallel with the connecting member. Therefore, when a power supply voltage input of the data line is unchanged, a resistance of the data line decreases, thereby improving a charging rate of the sub-pixel.

### BRIEF DESCRIPTION OF DRAWINGS

In order to more clearly illustrate the technical solutions in the embodiments of the present disclosure, a brief description of accompanying drawings used in the description of the embodiments of the present disclosure will be given below. Obviously, the accompanying drawings in the following description are merely some embodiments of the present disclosure. For those skilled in the art, other drawings may be obtained from these accompanying drawings without creative labor.

FIG. 1 is a schematic plan view of an array substrate according to an embodiment of the present disclosure.

FIG. 2 is a schematic diagram of a first structure of an array substrate according to an embodiment of the present disclosure.

FIG. 3 is a schematic diagram of a second structure of an array substrate according to an embodiment of the present disclosure.

FIG. 4 is a schematic plan view of the first structure of the array substrate according to the embodiment of the present disclosure.

FIG. 5 is a schematic plan view of the second structure of the array substrate according to the embodiment of the present disclosure.

### DETAILED DESCRIPTION

The following description of various embodiments of the present disclosure with reference to the accompanying drawings is used to illustrate specific embodiments that can be practiced. Directional terms mentioned in the present disclosure, such as “above”, “below”, “front”, “back”, “left”, “right”, “inside”, “outside”, “side”, are merely used to indicate the direction of the accompanying drawings. Therefore, the directional terms are used for illustrating and understanding the present disclosure rather than limiting the present disclosure. In the figures, elements with similar structures are indicated by the same reference numerals.

The present disclosure provides an array substrate and a display panel to solve the technical problem of insufficient charging rates of pixels of current display panels.

The present disclosure provides an array substrate comprising a plurality of sub-pixels disposed in an array. The array substrate further comprises a substrate, a first metal layer, an insulating layer, and a source/drain layer. The first metal layer is disposed on a side of the substrate and is patterned to form a plurality of scan lines. The scan lines extend in a horizontal direction and are disposed at intervals in a vertical direction. Each of the scan lines connects to a row of the sub-pixels. The insulating layer is disposed on a side of the first metal layer away from the substrate. The source/drain layer is disposed on a side of the insulating layer away from the first metal layer and is patterned to form a plurality of data lines. The data lines extend in the vertical direction and are disposed at intervals in the horizontal direction. Each of the data lines connects to a column of the sub-pixels. The sub-pixels comprise one or more first sub-pixels. The array substrate is provided with one or more connecting members corresponding to the first sub-pixels. A layer where the connecting members are located is insulated from the source/drain layer. The connecting members are not connected with other structures formed of the layer where the connecting members are located. The data lines connected to the first sub-pixels comprise first sub-data lines adjacent to the first sub-pixels. Both ends of each of the connecting members are connected to a corresponding first sub-data line through via holes.

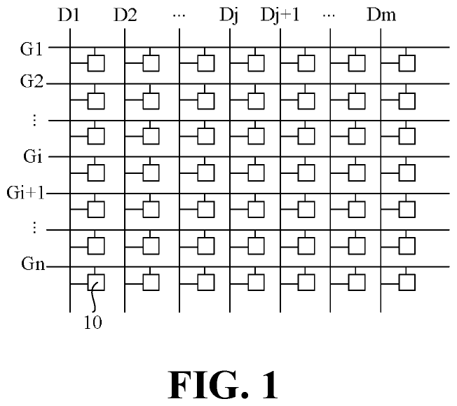

As shown in FIG. 1, in an array substrate of the present disclosure, a plurality of sub-pixels 10 are arranged in an array, forming a plurality of rows and columns. G1, G2, . . . , Gi, Gi+1, . . . , Gn represent first, second, . . . , i-th, i+1th . . . , n-th scan lines disposed at intervals from above to below in a vertical direction. Both i and n are positive integers and i<n. The scan lines extend in a horizontal direction. D1, D2, . . . , Dj, Dj+1, . . . , Dm represent first, second, . . . , j-th, j+1th m-th data lines disposed at intervals from left to right in the horizontal direction. Both j and m are positive integers and j<m. The data lines are perpendicular to the scan lines, that is, extends in the vertical direction. Each of the scan lines connects to a row of the sub-pixels 10, and each of the sub-pixels 10 in the row comprises a pixel driving circuit. After a display device enters a working state, a signal output terminal of each of the scan lines inputs a scan signal “Gate” to the pixel driving circuits, thereby turning on the m sub-pixels 10 of a corresponding row. Each of the m data lines inputs a data signal “Data” to the pixel driving circuit of each of the sub-pixels 10 in the row, so that each of the sub-pixels 10 displays a gray scale of a corresponding data signal “Data”.

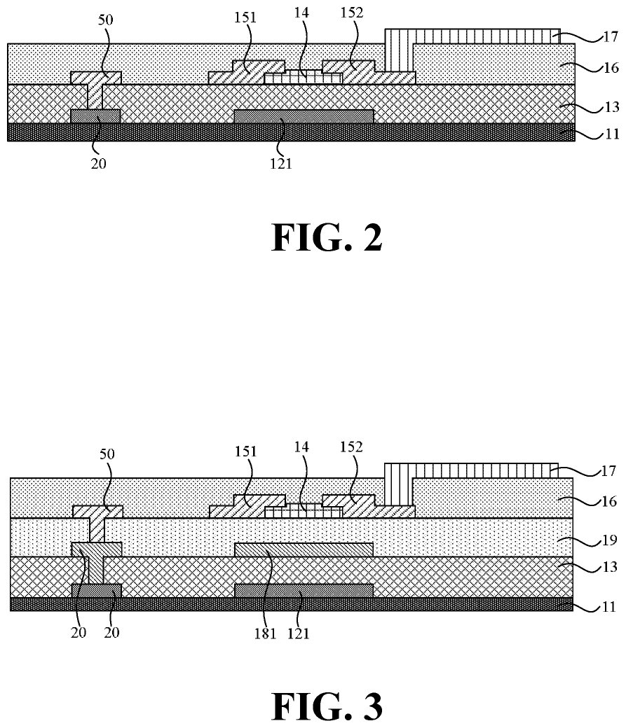

Please refer to FIG. 2, which is a schematic diagram of a structure of the array substrate. In this embodiment, as an example, a transistor in the array substrate has a bottom-gate structure, so an insulating layer between a first metal layer and a source/drain layer is a gate insulating layer 13. The array substrate comprises a substrate 11, the first metal layer, the gate insulating layer 13, an active layer 14, the source/drain layer, a passivation layer 16, and a pixel electrode 17 stacked from bottom to top.

The substrate 11 is usually made of glass. The first metal layer is patterned to form a gate electrode 121 of the thin film transistor and the scan lines (not shown). The active layer 14 comprises a source region and a drain region formed by doping N-type impurity ions or P-type impurity ions, and a channel region between the source region and the drain region. The active layer 14 may be made of amorphous silicon, polysilicon, or metal oxide. The metal oxide may be indium gallium zinc oxide. The source/drain layer is patterned to form a source electrode 151 and a drain electrode 152 of the thin film transistor, and the data lines (not shown). The source electrode 151 and the drain electrode 152 are respectively connected to the source region and the drain region of the active layer 14. The passivation layer 16 is formed on the source/drain layer and covers structures of the source/drain layer. The pixel electrode 17 is connected to the drain electrode 152 through a via hole in the passivation layer 16. The above structures together form the sub-pixel.

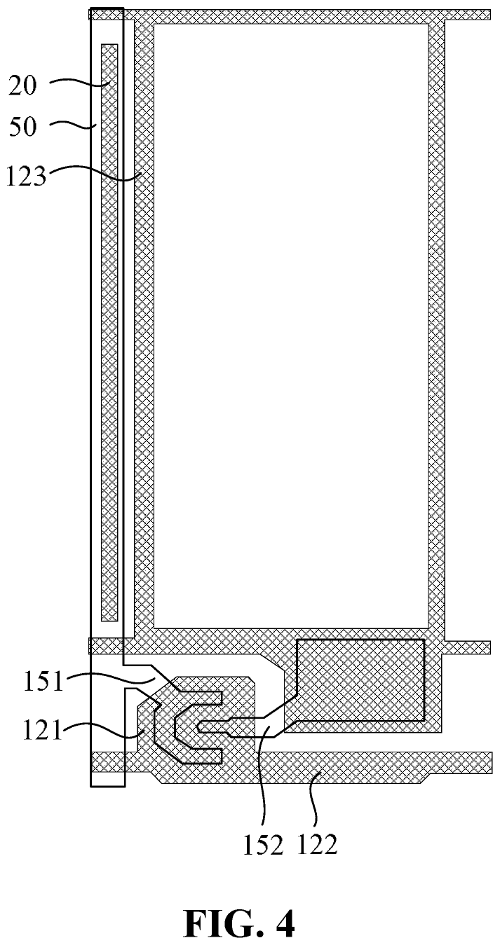

The sub-pixels in the array substrate comprise one or more first sub-pixels. Please refer to FIG. 4, which is a schematic plan view of a structure of the first sub-pixel. For convenience of presentation, FIG. 4 only shows the first metal layer and the source/drain layer. The first metal layer is patterned to form the gate electrode 121 of the transistor, the scan lines 122, and a shield electrode 123. The gate electrode 121 of the transistor is connected to a corresponding scan line 122. The source/drain layer is patterned to form the source electrode 151 and the drain electrode 152 of the transistor, and the data lines 50.

FIG. 4 shows the first sub-pixel with a four-domain structure as an example. The array substrate is provided with one or more connecting members 20 corresponding to the first sub-pixels. A layer where the connecting members 20 are located is insulated from the source/drain layer. The connecting members 20 are not connected with other structures formed of the layer where they are located. The data lines 50 connected to the first sub-pixels comprise first sub-data lines adjacent to the first sub-pixels, and both ends of each of the connecting members 20 are connected to a corresponding first sub-data line through via holes.

In the array substrate, each of the data lines 50 connects to a column of the sub-pixels, and is disposed on a side of the column of sub-pixels. Each of the data lines 50 may comprise a plurality of sub-data lines, each of the sub-data lines is adjacent to the sub-pixel connected to it, and the sub-data lines are sequentially connected to form the complete data line 50. Therefore, in the first sub-pixel of FIG. 4, the data lines 50 comprise first sub-data lines adjacent to the first sub-pixels, and both ends of each of the connecting members 20 are connected to a corresponding first sub-data line through via holes to form a parallel structure. Therefore, when a power supply voltage input of the data lines 50 is unchanged, a total resistance of the first sub-data lines and the connecting members decreases, thereby improving a charging rate of the first sub-pixels without increasing a thickness of the data lines 50. When all the sub-pixels in the array substrate are the first sub-pixels, a charging rate of the entire array substrate will be improved.

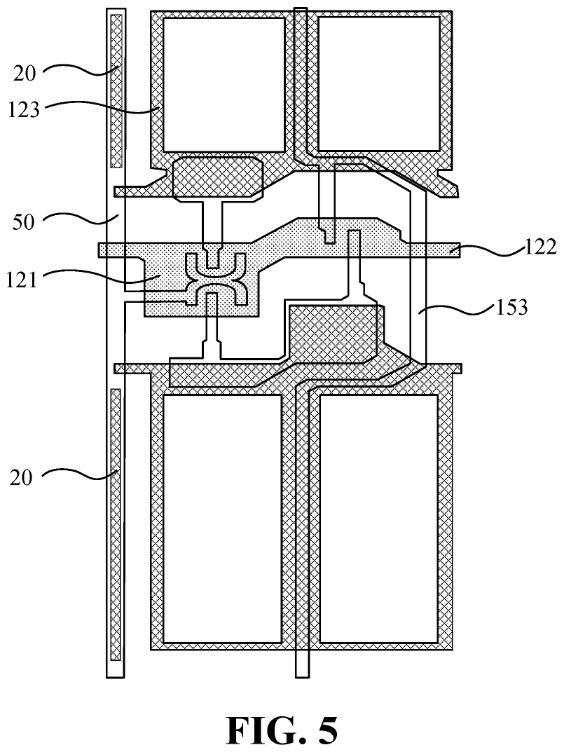

Corresponding to each of the first sub-pixels, the array substrate may be provided with only one connecting member 20 as shown in FIG. 4, or may be provided with two or more connecting members spaced apart from each other as shown in FIG. 5. The structure of FIG. 5 differs from the structure of FIG. 4 in that the first sub-pixel of FIG. 5 has an eight-domain structure and comprises a main pixel area disposed above the scan line 122 and an auxiliary pixel area disposed below the scan line 122. The source/drain layer further forms a shared electrode line 153. A portion of the first sub-pixel in the auxiliary pixel area leaks through the shared electrode line 153, so that in the first sub-pixel, a brightness of the main pixel area is different from a brightness of the auxiliary pixel area. Furthermore, the first sub-data line corresponding to the first sub-pixel also comprises two parts respectively disposed above and below the scan line 121. Each of the parts is provided with one of the connecting members 20, and the connecting members 20 do not contact each other. Both ends of each of the connecting members 20 are also connected to a corresponding first sub-data line through via holes.

In the embodiments of FIG. 4 and FIG. 5, the connecting members 20 are parallel to the first sub-data lines. A resistance of the connecting member 20 and the first sub-data line connected in parallel to each other is less than a resistance of the individual connecting member 20 and a resistance of the individual first sub-data line. In order to minimize resistance after parallel connection, the first is to maximize lengths of the first sub-data lines connected in parallel to the connecting members 20, and the second is to minimize a resistance of the connecting members 20. The law of resistance is R=ρL/S, wherein ρ is a resistivity, L is a resistance length, and S is a resistance cross-sectional area. When the connecting members 20 are made of a certain material, p is a constant value. The connecting members 20 can not be connected with other structures formed of a layer where they are located, so a range of increasing the cross-sectional area S is limited. Therefore, setting the connecting members 20 parallel to the first sub-data lines can minimize L, and can minimize the resistance of the connecting member 20 and the first sub-data line connected in parallel to each other, thereby achieving an optimal effect of improving charging rate.

The layer where the connecting members 20 are located is insulated from the source/drain layer, and it can be provided in various manners.

In an embodiment, as shown in FIG. 2, the connecting members 20 are formed of the first metal layer. The connecting members 20 are not in contact with the gate electrode 121 of the transistor, the scan lines (not shown), and the shield electrode (not shown) that are formed of the first metal layer. The connecting members 20 are only configured to be connected in parallel with the first sub-data lines to reduce the resistance of the first sub-data lines.

In an embodiment, as shown in FIG. 3, the array substrate further comprises a second metal layer disposed between and insulated from the first metal layer and the source/drain layer. In this case, the insulating layer between the first metal layer and the source-drain layer comprises the first gate insulating layer 13 and a second gate insulating layer 19. The array substrate comprises the substrate 11, the first metal layer, the gate insulating layer 13, the second metal layer, the second gate insulating layer 19, the active layer 14, the source/drain layer, the passivation layer 16, and the pixel electrode 17 stacked from bottom to top. In this case, the first metal layer further forms a first plate of a storage capacitor, in addition to forming the gate electrode 121 of the thin film transistor, the scan lines, and the shield electrode (not shown). The second metal layer forms a second plate of the storage capacitor. The connecting members 20 are formed of at least one of the first metal layer and the second metal layer. That is, the connecting members 20 may be formed of only the first metal layer or may be formed of only the second metal layer. Alternatively, as shown in FIG. 3, the connecting members 20 are formed of both the first metal layer and the second metal layer. The connecting members 20 formed of both the layers are connected in parallel with the first sub-data lines, and resistance after such parallel connection is smaller, thereby achieving a better effect of improving charging rate.

It should be noted that the embodiments of FIG. 2 and FIG. 3 use the bottom-gate structure as an example for description, but the present invention is not limited this. The material, arrangement, and technical effects of the connecting members of the present disclosure are applicable to an array substrate having a top-gate structure and an array substrate having a bottom-gate structure.

As shown in FIG. 1, in the array substrate, each of the scan lines connects to a row of the sub-pixels 10 in the horizontal direction. Each of the scan lines connects to a scan signal input terminal, receives a scan signal input from the scan signal input terminal, and then turns on the row of sub-pixels 10 connected thereto.

Common scanning methods are one-sided scanning and two-sided scanning. Taking one-sided scanning as an example, a scan signal “Gate” is input from a left side of a scan line to turn on an entire row of sub-pixels. However, in a large-sized display panel, a scan signal “Gate” transmitted from the leftmost side to the rightmost side is farther away, resulting in resistance/capacitance delays (RC Delays), which changes rectangular waveforms. Therefore, a time to turn on the sub-pixels farther from a scan signal input terminal will be shorter than a time to turn on the sub-pixels closer to the scan signal input terminal, which makes insufficient charging rates more serious when the data signal is input to the data line. Therefore, a first area may be selected in the array substrate, a distance between the first area and each of the scan signal input terminals being greater than a threshold. The first area comprises one or more columns of the sub-pixels, and all the sub-pixels in the first area are set as the first sub-pixels. The connecting members are provided corresponding to the first sub-pixels to increase a charging rate of each of the sub-pixels in the first area.

In an embodiment, the scan signal input terminals are disposed on a left or right side of the array substrate, and the first area is located on a side of a pixel area of the array substrate away from the scan signal input terminals. The pixel area of the array substrate is an area where all the sub-pixels are set. In this case, the array substrate adopts one-sided scanning. When the scan signal input terminals are disposed on the left side of the array substrate, the first area is located on a right side of the pixel area, and the distance between the first area and each of the scan signal input terminals is greater than a threshold. When the scan signal input terminals are disposed on the right side of the array substrate, the first area is located on a left side of the pixel area, and a distance between the first area and each of the scan signal input terminals is greater than a threshold.

In an embodiment, the scan signal input terminals are disposed on the left and right sides of the array substrate, and the first area is located in a middle of the pixel area of the array substrate. In this case, the array substrate adopts two-sided scanning. The first area is located in a middle of the pixel area, and a distance between the first area and each of the scan signal input terminals disposed on the left and right sides is greater than a threshold.

In an embodiment, the first area has a same size as the pixel area of the array substrate. That is, all the sub-pixels in the array substrate are the first sub-pixels. In this case, an effect of improving insufficient charging rate is the best.

In an embodiment, in the first area, the connecting members corresponding to the first sub-pixels are disposed in a same manner. That is, in the first area, the connecting members corresponding to the first sub-pixels have a same number, are located on same layers, and are connected in a same manner. In this case, a manufacturing process is relatively simple.

It can be understood from the above embodiments that in the present invention, a data line corresponding to at least one sub-pixel in an array substrate is connected to both ends of a connection member, so that the data line is connected in parallel with the connection member. Therefore, when a power supply voltage input of the data line is unchanged, a resistance of the data line decreases, thereby improving a charging rate of the sub-pixel.

The present disclosure further provides a liquid crystal display panel comprising an array substrate and a color film substrate disposed oppositely. The array substrate is the array substrate described in any of the above embodiments. The liquid crystal display panel of the present disclosure may be an 8K display panel with a resolution of 7680*4320, and may be applied to products such as mobile phones, computers, electronic watches, and flat panels. In the liquid crystal display panel of the present disclosure, a data line corresponding to at least one sub-pixel in an array substrate is connected to both ends of a connection member, so that the data line is connected in parallel with the connection member. Therefore, when a power supply voltage input of the data line is unchanged, a resistance of the data line decreases, thereby improving a charging rate of the sub-pixel, and making a display effect of the liquid crystal display panel better.

It can be understood from the above embodiments that:

The present disclosure provides an array substrate and a display panel. The array substrate comprises a plurality of sub-pixels disposed in an array. The array substrate further comprises a substrate, a first metal layer, an insulating layer, and a source/drain layer. The first metal layer is disposed on a side of the substrate and is patterned to form a plurality of scan lines. The scan lines extend in a horizontal direction and are disposed at intervals in a vertical direction. Each of the scan lines connects to a row of the sub-pixels. The insulating layer is disposed on a side of the first metal layer away from the substrate. The source/drain layer is disposed on a side of the insulating layer away from the first metal layer and is patterned to form a plurality of data lines. The data lines extend in the vertical direction and are disposed at intervals in the horizontal direction. Each of the data lines connects to a column of the sub-pixels. The sub-pixels comprise one or more first sub-pixels. The array substrate is provided with one or more connecting members corresponding to the first sub-pixels. A layer where the connecting members are located is insulated from the source/drain layer. The connecting members are not connected with other structures formed of the layer where the connecting members are located. The data lines connected to the first sub-pixels comprise first sub-data lines adjacent to the first sub-pixels. Both ends of each of the connecting members are connected to a corresponding first sub-data line through via holes. In the present invention, a data line corresponding to at least one sub-pixel in an array substrate is connected to both ends of a connecting member, so that the data line is connected in parallel with the connecting member. Therefore, when a power supply voltage input of the data line is unchanged, a resistance of the data line decreases, thereby improving a charging rate of the sub-pixel.

In the above embodiments, the description of each embodiment has its own emphasis. For parts that are not described in detail in one embodiment, reference may be made to related descriptions in other embodiments.

The array substrate and the display panel provided by the embodiments of the present disclosure are described in detail above. The present disclosure uses specific examples to describe principles and embodiments of the present application. The above description of the embodiments is only for helping to understand the technical solutions of the present disclosure and its core ideas. It should be understood by those skilled in the art that they can modify the technical solutions recited in the foregoing embodiments, or replace some of technical features in the foregoing embodiments with equivalents. These modifications or replacements do not cause essence of corresponding technical solutions to depart from the scope of the technical solutions of the embodiments of the present disclosure.

1. An array substrate, comprising a plurality of sub-pixels disposed in an array and further comprising:
a substrate;
a first metal layer disposed on a side of the substrate and patterned to form a plurality of scan lines, wherein the scan lines extend in a horizontal direction and are disposed at intervals in a vertical direction, and each of the scan lines connects to a row of the sub-pixels;
an insulating layer disposed on a side of the first metal layer away from the substrate; and
a source/drain layer disposed on a side of the insulating layer away from the first metal layer and patterned to form a plurality of data lines, wherein the data lines extend in the vertical direction and are disposed at intervals in the horizontal direction, and each of the data lines connects to a column of the sub-pixels;
wherein, the sub-pixels comprise one or more first sub-pixels, the array substrate is provided with one or more connecting members corresponding to the first sub-pixels, the data lines connected to the first sub-pixels comprise first sub-data lines adjacent to the first sub-pixels, and both ends of each of the connecting members are connected to a corresponding first sub-data line through via holes.

2. The array substrate according to claim 1, wherein the connecting members are formed of the first metal layer.

3. The array substrate according to claim 1, further comprising a second metal layer disposed between and insulated from the first metal layer and the source/drain layer, wherein the first metal layer further forms a first plate of a storage capacitor, the second metal layer further forms a second plate of the storage capacitor, and the connecting members are formed of at least one of the first metal layer and the second metal layer.

4. The array substrate according to claim 1, wherein the connecting members are parallel to the first sub-data lines.

5. The array substrate according to claim 1, wherein the array substrate is provided with two or more of the connecting members corresponding to the first sub-pixels and spaced apart from each other.

6. The array substrate according to claim 1, further comprising a first area, wherein the first area comprises one or more columns of the first sub-pixels, each of the scan lines is connected to a scan signal input terminal, and a distance between the first area and each of the scan signal input terminals is greater than a threshold.

7. The array substrate according to claim 6, wherein the scan signal input terminals are disposed on a left or right side of the array substrate, and the first area is located on a side of a pixel area of the array substrate away from the scan signal input terminals.

8. The array substrate according to claim 6, wherein the scan signal input terminals are disposed on left and right sides of the array substrate, and the first area is located in a middle of a pixel area of the array substrate.

9. The array substrate according to claim 6, wherein the first area has a same size as a pixel area of the array substrate.

10. The array substrate according to claim 6, wherein in the first area, the connecting members corresponding to the first sub-pixels are disposed in a same manner.

11. A liquid crystal display panel, comprising an array substrate and a color film substrate disposed oppositely, wherein the array substrate comprises a plurality of sub-pixels disposed in an array and further comprises:
a substrate;
a first metal layer disposed on a side of the substrate and patterned to form a plurality of scan lines, wherein the scan lines extend in a horizontal direction and are disposed at intervals in a vertical direction, and each of the scan lines connects to a row of the sub-pixels;
an insulating layer disposed on a side of the first metal layer away from the substrate; and
a source/drain layer disposed on a side of the insulating layer away from the first metal layer and patterned to form a plurality of data lines, wherein the data lines extend in the vertical direction and are disposed at intervals in the horizontal direction, and each of the data lines connects to a column of the sub-pixels;
wherein, the sub-pixels comprise one or more first sub-pixels, the array substrate is provided with one or more connecting members corresponding to the first sub-pixels, the data lines connected to the first sub-pixels comprise first sub-data lines adjacent to the first sub-pixels, and both ends of each of the connecting members are connected to a corresponding first sub-data line through via holes.

12. The liquid crystal display panel according to claim 11, wherein the connecting members are formed of the first metal layer.

13. The liquid crystal display panel according to claim 11, wherein the array substrate further comprises a second metal layer disposed between and insulated from the first metal layer and the source/drain layer, the first metal layer further forms a first plate of a storage capacitor, the second metal layer further forms a second plate of the storage capacitor, and the connecting members are formed of at least one of the first metal layer and the second metal layer.

14. The liquid crystal display panel according to claim 11, wherein the connecting members are parallel to the first sub-data lines.

15. The liquid crystal display panel according to claim 11, wherein the array substrate is provided with two or more of the connecting members corresponding to the first sub-pixels and spaced apart from each other.

16. The liquid crystal display panel according to claim 11, wherein the array substrate further comprises a first area, the first area comprises one or more columns of the first sub-pixels, each of the scan lines is connected to a scan signal input terminal, and a distance between the first area and each of the scan signal input terminals is greater than a threshold.

17. The liquid crystal display panel according to claim 16, wherein the scan signal input terminals are disposed on a left or right side of the array substrate, and the first area is located on a side of a pixel area of the array substrate away from the scan signal input terminals.

18. The liquid crystal display panel according to claim 16, wherein the scan signal input terminals are disposed on left and right sides of the array substrate, and the first area is located in a middle of a pixel area of the array substrate.

19. The liquid crystal display panel according to claim 16, wherein the first area has a same size as a pixel area of the array substrate.

20. The liquid crystal display panel according to claim 16, wherein in the first area, the connecting members corresponding to the first sub-pixels are disposed in a same manner.
